(19) United States
(12) Patent Application Publication
(10) Pub. No.: US 2007/0162820 A1
(43) Pub. Date: Jul. 12, 2007

(54) Checksum generation apparatus and method thereof

(76) Inventor: Hyun-Seok Choi, Seoul (KR)

Correspondence Address: STEIN, MCEWEN & BUI, LLP, 1400 EYE STREET, NW, SUITE 300, WASHINGTON, DC, 20005, US

(21) Appl. No.: 10/584,093

(22) PCT Filed: Dec. 10, 2004
(86) PCT No.: PCT/KR04/03249

§ 371 Date: Jun. 16, 2006

(30) Foreign Application Priority Data
Dec. 16, 2003 (KR) 2003-91882

(51) Int. Cl. H03M 13/00

(52) U.S. Cl. 714/758

(57) ABSTRACT

A checksum generation apparatus and method thereof. The checksum generation apparatus includes a control unit which, in response to information on a predetermined length, outputs a control signal when an amount of data corresponding to the predetermined length is received; an addition unit which receives data, performs an addition on the received data, and, in response to the control signal, outputs an addition result; and a conversion unit which converts the addition result to a checksum.

### TECHNICAL FIELD

The present invention relates to data processing, and more particularly, to a checksum generation apparatus and a method thereof used to determine whether data is transmitted and received without its errors.

### BACKGROUND ART

A checksum calculation is to count bit number in a transmission unit of data in order to determine whether received data has the same bit number as data transmitted by a transmitter. If a checksum calculated by a receiver matches a checksum transmitted by the transmitter, it is determined that the data is received without its errors. Checksum calculation and determination are performed in a transmission control protocol (TCP) and a user datagram protocol (UDP) of internet protocols.

The checksum calculation is one of the most important data processing in the internet protocols. In addition, it is necessary to calculate the checksum at a high speed. A conventional checksum calculation method has a problem that its calculation speed is too low since its abler processes data in units of 16 bits.

### DISCLOSURE OF INVENTION

### Technical Solution

The present invention provides a checksum generation apparatus and a method thereof capable of improving a checksum calculation speed by performing an addition in units of 32 bits or more and converting an addition result to a 16-bit checksum.

### Advantageous Effects

According to the present invention, it is possible to increase a checksum calculation speed by not dividing input data. In particular, when the checksum generation apparatus is implemented in an ASIC device, it is possible to increase a calculation speed of a checksum generation apparatus by using 32-bit or 64-bit abler in a library of the ASIC device.

### DESCRIPTION OF DRAWINGS

FIG. 1 is a view for explaining a method of generating a checksum;

FIG. 2 is a block diagram illustrating a checksum generation apparatus according to an embodiment of the present invention;

FIG. 3 is a detailed block diagram illustrating a checksum generation apparatus using a 32-bit abler;

FIG. 4 is a detailed block diagram illustrating a checksum generation apparatus using a 64-bit abler;

FIG. 5A is a view illustrating a TCP segment format;

FIG. 5B is a view illustrating a pseudo header format; and

FIG. 6 is a flowchart illustrating a method of generating a checksum according to an embodiment of the present invention.

### BEST MODE

According to an aspect of the present invention, there is provided a checksum generation apparatus, comprising: a control unit which, in response to information on a predetermined length, outputs a control signal when an amount of data corresponding to the predetermined length is received; an addition unit which receives data, performs an addition on the received data, and, in response to the control signal, outputs an addition result; and a conversion unit which converts the addition result to a checksum.

It is preferable that the addition unit receive data in units of 32 bits plus (an integer X 16 bits) and perform an addition on the received data.

In addition, it is preferable that the conversion unit divide the addition result into a sum and a carry, partition the sum into 16-bit segments, and add the 16-bit segments to the carry, thereby obtaining a final sum.

In addition, it is preferable that the conversion unit comprise: a partial sum addition unit for excluding a carry from the addition result, partitioning a carry-excluded addition result into 16-bit segments, adding the 16-bit segments, thereby obtaining a partial sum; a first adder for adding the carry to the partial sum; a second adder for adding an addition result of the first adder and a carry occurring in the addition result; and a complement calculator for outputting a 1's complement value of the addition result of the second adder.

According to another aspect of the present invention, there is provided a method of generating a checksum, the method comprising the steps of: (a) adding input data until a predetermined control signal is received; (b) outputting a sum and a carry obtained from the addition result when the control signal is received; and (c) adding the sum and the carry and converting the addition result to a checksum.

In addition, it is preferable that, in the step (a), data be received in units of 32 bits plus (an integer X 16 bits) and an addition be performed on the received data.

In addition, it is preferable that, the step (b) further comprises the steps of: (b1) adding the received data in units of 32 bits plus (an integer X 16 bits); and (b2) adding carries generated in the step (b1).

In addition, it is preferable that, the step (c) further comprise the steps of: (c1) excluding a carry from the addition result, partitioning a carry-excluded addition result into 16-bit segments, adding the 16-bit segments, thereby obtaining a partial sum; (c2) adding the carry to the partial sum; (c3) adding an addition result of the step (c2) and a carry occurring in the addition result; and (c4) outputting a 1's complement value of the addition result of the step (c3).

According to still another aspect of the present invention, there is provided a computer-readable storage medium where a program executed by a computer is stored, the program comprising the aforementioned method.

### MODE FOR INVENTION

The present invention and operational advantages thereof can be fully understood by referring to the accompanying drawings and explanations thereof.

Now, exemplary embodiments of the present invention will be described with reference to the accompanying drawings to explain the present invention in detail. In the drawings, the same reference numerals indicate the same elements.

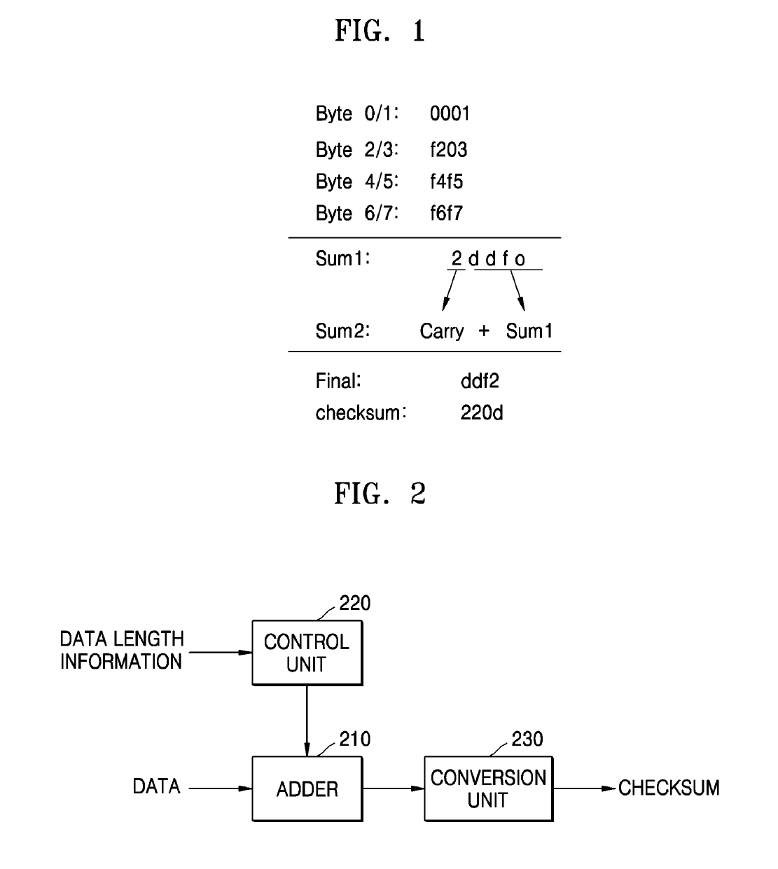

FIG. 1 is a view for explaining a method of generating a checksum.

A 16-bit abler is used for the method of generating the checksum. Firstly, data (0001 f203 f4f5 f6f7) is divided into 16-bit data segments and a first addition is performed on the 16-bit data segments. That is, the first addition is 0001+f203+f4f5+f6f7. The first addition value Sum1 is 2ddf0. Since the 16-bit abler is used a carry of the first addition value Sum 1 is 2. In a second addition, the carry of the first addition value Sum1 is added back to the 16-bit abler to obtain a second addition value Sum2, that is, a final value: 2+dif0=ddf2. The checksum is obtained by performing a 1's complement operation on the final value ddf2. Therefore, the checksum is 220d. The checksum calculation is disclosed in the RFC1071 document in detail.

FIG. 2 is a block diagram illustrating a checksum generation apparatus according to an embodiment of the present invention.

A checksum generation apparatus comprises an addition unit 210, a control unit 220, and a conversion unit 230. Data in units of a 32-bit or 64-bit segment is input to the addition unit 210. In some cases, the data may be input in units of more than 64-bit segment. The addition unit 210 may be constructed with a 32-bit or 64-bit adder. Moreover, the addition unit 210 may be constructed with an 80-bit, 96-bit, or 128-bit adder. In the present invention, the input data is not divided into 16-bit data segments but added as it is. In response to information on a predetermined input data length, the control unit 220 determines whether the input data corresponding to the input data length is received and accumulated. When the input data corresponding to the length is received the control unit 220 outputs a control signal to the addition unit 210. In response to the control signal, the addition unit 210 outputs its addition value to the conversion unit 230. The conversion unit 230 converts the addition value to a 16-bit checksum and outputs the checksum.

The addition unit 210 accumulates and adds the input data to obtain a partial sum until the control signal is received from the control unit 220. A carry addition is separately performed. In consideration of a maximum value of the carry, a result of the carry addition, that is, a carry sum, is stored in units of 10 bits. When the control signal is received from the control unit 220, the partial and carry sums are output to the conversion unit 230. The conversion unit 230 divides the partial sum in 16-bit segments and adds the 16-bit segments. The result of the addition is added back to the carry sum to obtain the final sum. The conversion unit 230 output a 1's complement value of the final sum. For example, assuming that the addition unit 210 performs the addition in units of 32 bits and the partial sum is a 32-bit value, the conversion units 230 obtains the final sum by adding higher 16 bits and lower 16 bits of the 32-bit partial sum to the carry. In addition, assuming that the addition unit 210 performs the addition in units of 64 bits and the partial sum is a 64-bit value, the conversion units 230 obtains the final sum by adding most significant 16 bits, higher 16 bits, and lower 16 bits, and least significant 16 bit of the 64-bit partial sum to the carry.

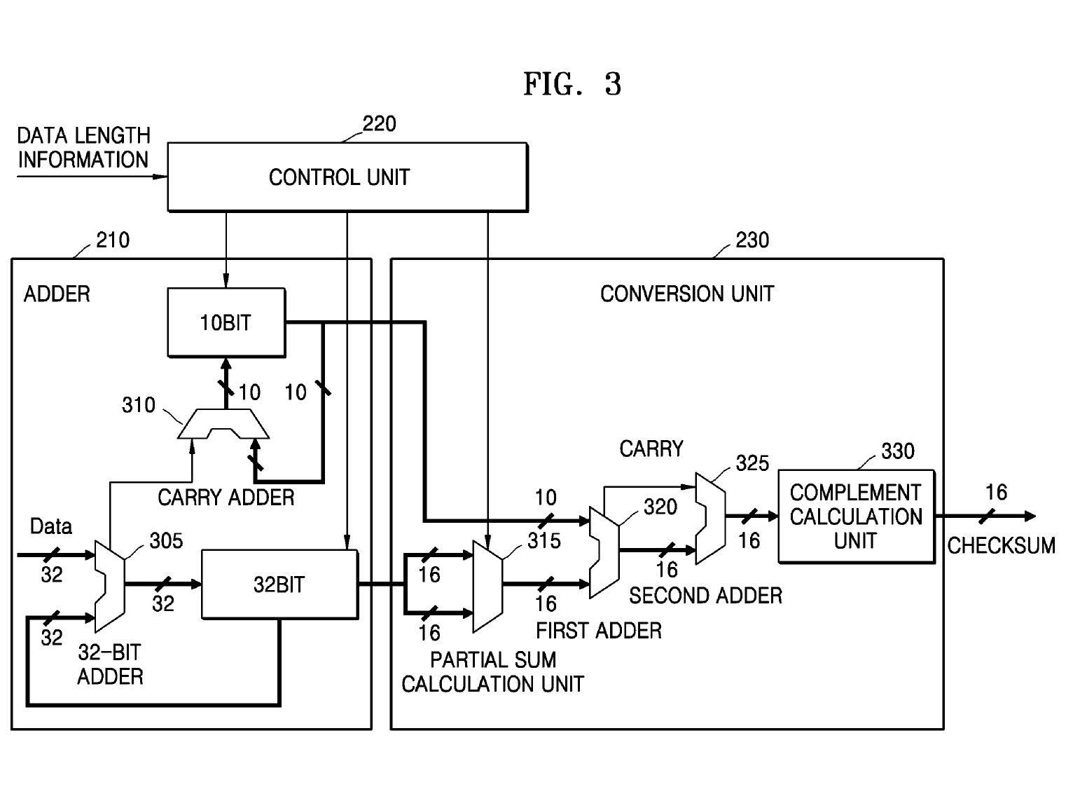

FIG. 3 is a detailed block diagram illustrating a checksum generation apparatus using a 32-bit adder.

An addition unit 210 comprises a 32-bit adder 305 and a carry adder 310. The 32-bit adder 305 adds input data, and the carry adder 310 adds carries. The conversion unit 230 comprises a partition adder 315, a first adder 320, and a second adder 325, and a complement calculator 330. The partition adder 315 partitions 32-bit data into high 16-bit data segment and low 16-bit data segment and adds the 16-bit data segments. The addition result is added back to a carry output from the carry adder in the first adder 320. The second adder adds an addition result of the first adder 320 310 to the carries and outputs a final sum, which has a 16 bit value. The complement calculator 330 outputs a 1's complement value of the final sum.

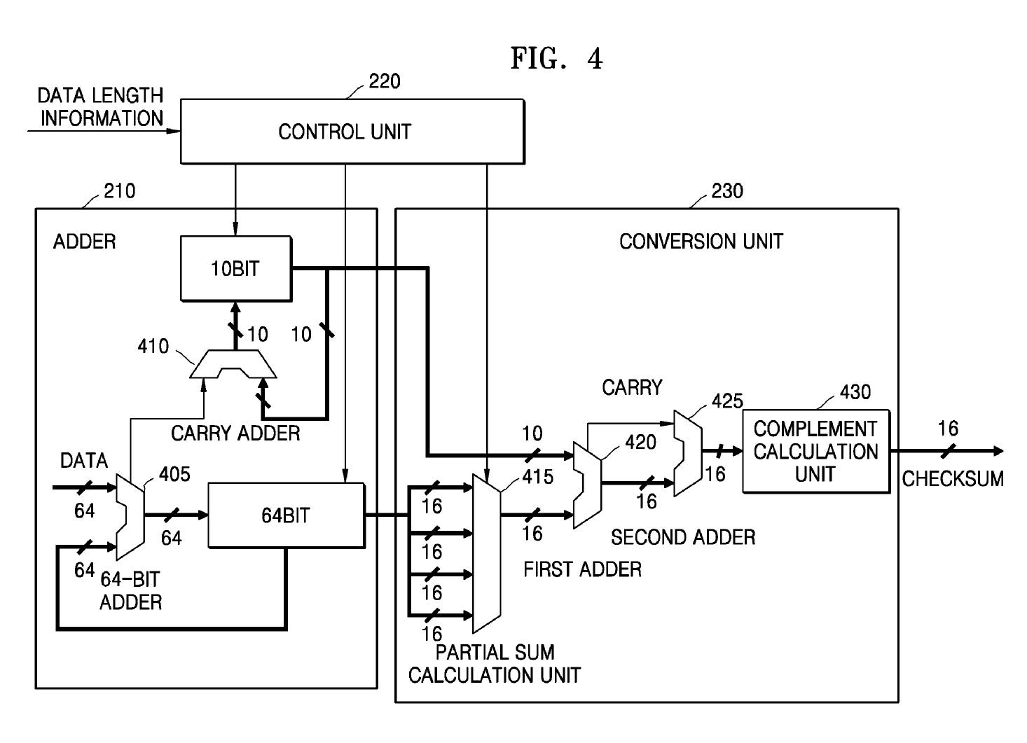

FIG. 4 is a detailed block diagram illustrating a checksum generation apparatus using a 64-bit adder.

An addition 210 comprises a 64-bit adder 405 and a carry adder 410. The 32-bit adder 405 adds input data, and the carry abler 410 adds carries. The conversion unit 230 comprises a partition adder 415, a first adder 420, and a second adder 425, and a complement calculator 430. The partition adder 415 partitions 62-bit data into four 16-bit data segments and adds the four 16-bit data segments. The other components are the same as the 32-bit adder.

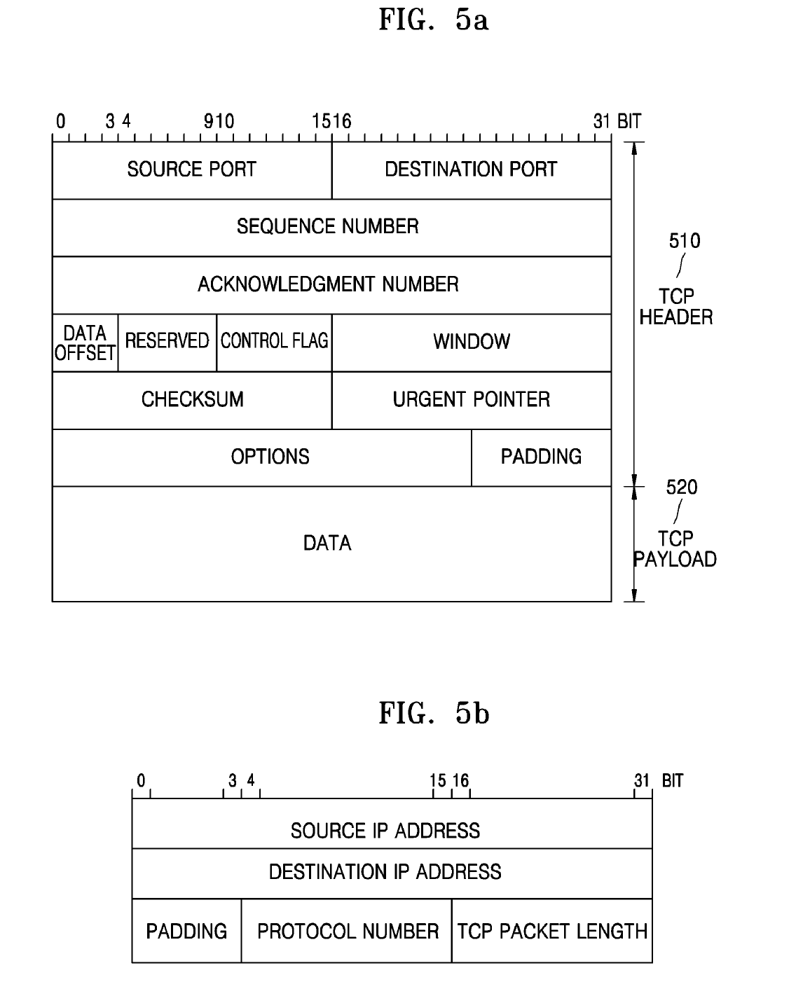

The checksum calculation described above can be employed to any protocols such as protocols IP, TCP, and UDP. Now, a checksum calculation employed in the protocol TCP will be described in detail with reference to FIGS. 5A and 5B.

FIG. 5A is a view illustrating a TCP segment format.

The TCP segment has a TCP header 510 and a TCP payload 520. The TCP header 510 has a checksum field where a checksum is entered. A pseudo header is needed in order to calculate the checksum in a protocol TCP. Other fields in the TCP segment are well known to the skilled so their detailed descriptions are omitted.

FIG. 5B is a view illustrating a pseudo header format.

A pseudo header comprises a source IP address, a destination IP address, padding, a protocol number, a TCP packet length. The pseudo header is not really transmitted but used to calculate a checksum of a TCP packet. End portion of data has a value of 0 by a padding operation in order that the data length is a multiple of 16 bits. A checksum field of the TCP header has a value of 1. An addition is performed in units of 16 bits. A 1's complement of the addition result is entered into the checksum field. When receiving TCP segments, the receiver obtains an IP address from an IP header, produces a TCP pseudo header, and calculates a checksum.

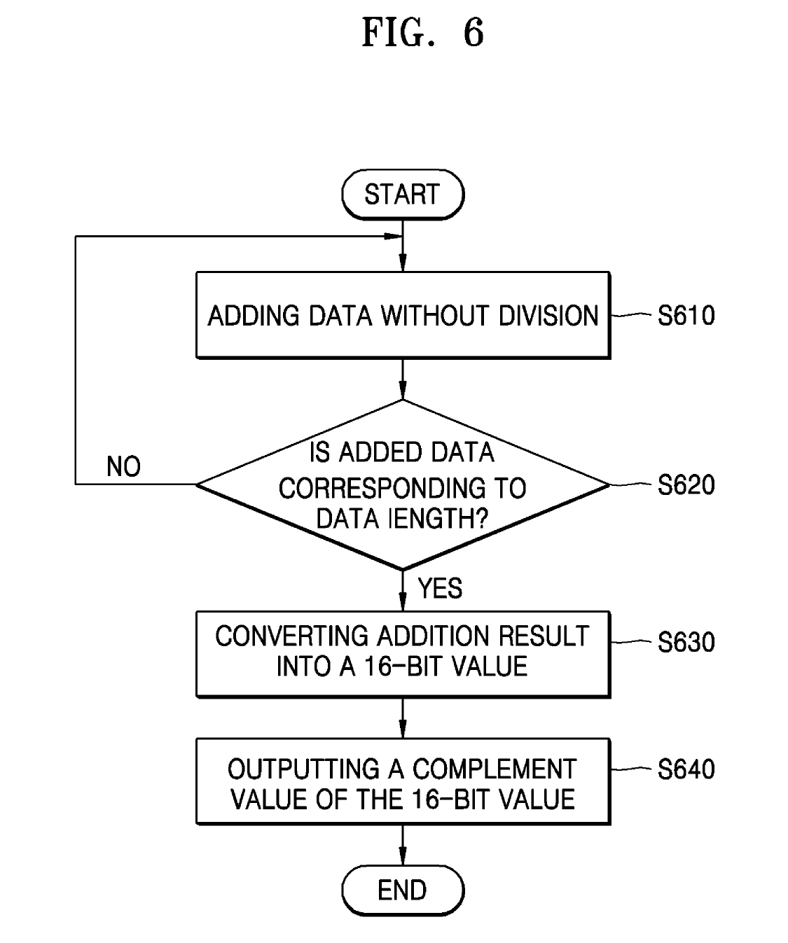

FIG. 6 is a flowchart illustrating a method of generating a checksum according to an embodiment of the present invention.

The input data is not divided into 16-bit data segments but added as it is (S610). Carries occurring in addition results are separately flued together. The addition result of the carries is stored in units of 10 bits in consideration of a maximum value of the carries. It is determined whether the input data corresponding to the input data length is received and accumulated (S620). Until the input data corresponding to the length is received the input data is added. The addition result is converted to a 16-bit value (S630). A 1's complement of the 16-bit value is output (S640).

Now, the step S630 in a case where the input data has a 16-bit value will be described in detail. The addition result and its carry are indicated by Sum1 and Carry1, respectively. Therefore, Temp1=(16-bit MSB of Sum1)+(16-bit LSB of Sum1)+Carry1. If a carry of Temp1 is indicated by Carry2, Temp2=(Temp1)+(Carry2). The value Temp1 becomes a 16-bit final value. In a case where the input data has a 64-bit value, the value Temp1 is obtained by adding four 16-bit segments and a carry. The value Temp2 is obtained by the same calculation as described above.

The above described method of generating a checksum can be implemented with a program. Codes and code segments constituting the program can be easily deduced by the skilled in the art. In addition, the program is stored in a computer-readable storage medium. The program is read and executed by a computer. The computer-readable storage medium includes a magnetic storage medium, an optical storage medium, and a carrier wave medium.

1. A checksum generation apparatus, comprising:
a control unit which, in response to information on a predetermined length, outputs a control signal when an amount of data corresponding to the predetermined length is received;
an addition unit which performs an addition on the received data, and, in response to the control signal, outputs an addition result; and
a conversion unit which converts the addition result to a checksum.

2. The checksum generation apparatus according to claim 1, wherein the checksum has a value of 16 bits.

3. The checksum generation apparatus according to claim 1, wherein the addition unit receives data in units of n*16 bits, where n is an integer greater than or equal to 2, and performs an addition on the received data.

4. The checksum generation apparatus according to claim 1, wherein the conversion unit divides the addition result into a sum and a carry, partitions the sum into 16-bit segments, and adds the 16-bit segments to the carry, thereby obtaining a final sum.

5. The checksum generation apparatus according to claim 4, wherein, when a carry occurs in the final sum, the conversion unit excludes the carry from the final sum and adds the carry to the carry-excluded final sum, thereby outputting a carry-added final sum.

6. The checksum generation apparatus according to claim 5, wherein the conversion unit outputs a 1's complement value of the carry-added final sum as a 16-bit checksum.

7. The checksum generation apparatus according to claim 1, wherein the addition unit comprises:
an adder adding the received data in units of n*16 bits, where n is an integer greater than or equal to 2; and
a carry adder adding carries generated in the adder.

8. The checksum generation apparatus according to claim 1, wherein the conversion unit comprises:
a partial sum addition unit excluding a carry from the addition result, partitioning the carry-excluded addition result into 16-bit segments, adding the 16-bit segments, to obtain a partial sum;
a first adder adding the carry to the partial sum;
a second adder adding an addition result of the first adder and a carry occurring in the addition result of the first adder; and
a complement calculator outputting a 1's complement value of the addition result of the second adder.

9. A method of generating a checksum, the method comprising:
adding input data until a predetermined control signal is received;
outputting a sum and a carry obtained from the addition result when the control signal is received; and
adding the sum and the carry and converting the added sum and carry to a checksum.

10. The method of generating a checksum according to claim 9, wherein the checksum is converted to a value of 16 bits.

11. The method of generating a checksum according to claim 9, wherein the control signal is output when an amount of data corresponding to input data length information is received.

12. The method of generating a checksum according to claim 9, wherein the data is received in units of n*16 bits, where n is an integer greater than or equal to 2 and an addition is performed on the received data.

13. The method of generating a checksum according to claim 9, wherein, the adding of the sum and the carry comprises:
partitioning the sum into 16-bit segments, and
adding the 16-bit segments to the carry, to obtain a final sum.

14. The method of generating a checksum according to claim 13, wherein, when a second carry occurs in the final sum, the second carry is excluded from the final sum and added to the carry-excluded final sum, to output a carry-added final sum.

15. The method of generating a checksum according to claim 14, further comprising:
outputting a 1's complement value of the carry-added final sum as a 16-bit checksum.

16. The method of generating a checksum according to claim 9, wherein the outputting of the sum and carry comprises:
adding the received data in units of n*16 bits, where n is an integer greater than or equal to 2; and
adding carries generated in adding of the received data.

17. The method of generating a checksum according to claim 9, wherein the adding of the sum and the carry and the converting of the added sum and carry to a checksum comprises:
excluding the carry from the addition result, partitioning a carry-excluded addition result into 16-bit segments, and adding the 16-bit segments, to obtain a partial sum;
adding the carry to the partial sum to obtain a second addition result and a second carry;
adding the second addition result and the second carry to obtain a third addition result; and
outputting a 1's complement value of the third addition result as the checksum.

18. A computer-readable storage medium storing a program executable by a computer, the program comprising instructions for enabling the computer to perform a method of generating a checksum, wherein the program comprises:
instructions for adding input data until a predetermined control signal is received;
instructions for outputting a sum and a carry obtained from an addition result when the control signal is received; and
instructions for adding the sum and the carry and converting the added sum and carry to a checksum.

19. An apparatus for generating a checksum, the apparatus comprising:
a first adder adding a predetermined number of bits of input data received in units of n*m bits, where n is a first integer greater than or equal to 2 and m is a second integer, to obtain a first sum having n*m bits and a first carry;
a partial sum calculator partitioning the first sum into n segments of m bits and adding the m-bit segments to obtain a second sum;
a second adder adding the second sum and the first carry to obtain a third sum and a second carry;
a third adder adding the third sum and the second carry to obtain a fourth sum; and
a complement calculator outputting a 1's complement value of the fourth sum as an m-bit checksum.

20. An apparatus for generating a checksum, the apparatus comprising:
a first adder adding a predetermined number of bits of input data received in units of n*m bits, where n is a first integer greater than or equal to 2 and m is a second integer, to obtain a first sum having n*m bits and a first carry;
a partial sum calculator partitioning the first sum into n segments of m bits and adding the m-bit segments to obtain a second sum;
a second adder adding the second sum and the first carry to obtain a third sum; and
a complement calculator outputting a 1's complement value of the third sum as an m-bit checksum.

21. A method of generating a checksum for input data received in units of n*m bits, where n is a first integer greater than or equal to 2 and m is a second integer n, the method comprising:
adding a predetermined number of the input data units without dividing the input data units into smaller units, to obtain a first sum having n*m bits and a first carry;
partitioning the first sum into n segments of m bits and adding the m-bit segments to obtain a second sum;
adding the second sum and the first carry to obtain a third sum; and
outputting a 1's complement value of the third sum as an m-bit checksum.

22. The method of claim 21, wherein:
if a second carry is generated in the adding of the second sum and the first carry, the method further comprises:
adding the third sum and the second carry to obtain a fourth sum, and
replacing the third sum with the fourth sum in the outputting of the 1's complement value as the m-bit checksum.
